(19) United States
(12) Patent Application Publication
(10) Pub. No.: US 2011/0278614 A1
(43) Pub. Date: Nov. 17, 2011

(54) LIGHT EMITTING DEVICE, AND METHOD FOR THE PRODUCTION THEREOF

(75) Inventors: Andrea Maier-Richter, Hong Kong (CN); Rolf Wehrmann, Krefeld (DE); Michael Erkelenz, Duisburg (DE); Anke Boumans, Goch (DE)

(73) Assignee: Bayer MaterialScience AG, Leverkusen (DE)

(21) Appl. No.: 13/062,355

(22) PCT Filed: Aug. 28, 2009
(86) PCT No.: PCT/EP2009/006250

§ 371 Date: Jun. 30, 2011

(30) Foreign Application Priority Data
Sep. 4, 2008 (EP) 08015572.4

(51) Int. Cl. H01L 33/50; C08K 3/08

(52) U.S. Cl. 257/98; 524/440; 257/E33.061

(57) ABSTRACT

The present invention relates to a composition of plastic material that includes from 7 to 20 wt. % inorganic conversion pigments. The pigments include Si, Sr, Ba, Ca and Eu in concentrations of greater than 0 ppm and Al, Co, Fe, Mg, Mo, Na, Ni, Pd, P, Rh, Sb, Ti and Zr in concentrations of less than or equal to 50 ppm

The invention relates to a light-emitting device containing a plastics moulded body with which, in combination with a plastic moulding and, for example, blue LEDs (light-emitting diodes) or UV-LEDs, which are located in cavities in the plastics moulded body, white light can be produced.

The invention relates additionally to a composition of plastics material containing specific inorganic conversion pigments in specific concentration ranges, which are suitable, for example, for the production of those plastics moulded bodies.

For use in the lighting of the human environment (ambient lighting), the lighting industry is interested in particular in light sources which produce white light with a good colour reproduction, because this is most similar to natural light.

Inorganic LEDs (light-emitting diodes) and LED DIEs (LED chips) are distinguished by a long life, small size, insensitivity to vibrations, and narrow-band spectral emission. On account of their low energy consumption, LEDs especially, but also electroluminescent lamps, have in recent years become increasingly more interesting as light sources.

The emission colours, which cannot be produced by the LEDs or LED DIEs themselves, are produced by means of external colour conversion. So-called conversion substances or conversion pigments are arranged around the LEDs or LED DIEs. The absorbed radiation excites the conversion pigments to photoluminescence. Organic or inorganic pigments can in principle be used as conversion pigments.

Such inorganic light sources in the form of LEDs or LED DIEs have the disadvantage, however, that they emit only monochromatic light, that is to say light of only one spectral colour. In the case of LEDs, those colours are in particular the spectral colours blue, green, yellow, orange, red, violet or monochromatic UV light (UV-LEDs), and in the case of electroluminescent lamps they are in particular the spectral colours blue, green or orange. LEDs that emit white light without further assistance are technically not possible.

In order to remedy this disadvantage, white light sources based on LEDs are produced by various methods.

Basically, organic and inorganic conversion pigments are used to produce white light with the monochromatic light-emitting elements. To that end, the light-emitting elements are suitably combined with the conversion pigments.

The colour of the emitted white light (light temperature) is thereby dependent on the conversion pigment, its concentration, and on the wavelength of the light-emitting element. The homogeneity of the emitted light is determined by the uniformity of the distribution of the conversion pigment on the light-emitting element or the light-emitting device.

Thus, for example, conversion pigments can absorb some of the blue light of an LED and emit yellow light. The additive colour mixture of the remaining blue light and the yellow light produced by a colour layer yields white light.

In principle, the chromaticity coordinate can be set on a line between the chromaticity coordinates of the blue LED and of the conversion pigment in the CIE 1931 chromaticity diagram. The blue LEDs used have an emission peak at 240 to 510 nm, at 300 to 500 nm, especially at 400 to 490 nm, most particularly at 450 to 480 nm and in particular at 460 to 470 nm. In a most particularly preferred case, the emission peak is between 460 and 470 nm, preferably at 464 nm.

A method of producing white light is the “glob top casting method”, in which viscous, transparent silicone is mixed with yellow or green phosphors and the mixture is applied in the form of a drop (“glob top”) to a blue LED DIE in the so-called dispensing method (VDI reports no. 2006, 2007).

Another method is carried out in a similar manner to the above-mentioned method, but a multiple phosphor or a mixture of different suitable phosphors is used.

As a further variant of the first-mentioned method it is also possible to use a UV LED with “RGB phosphor” (three-colour phosphor). As yet, this variant is not often used because the UV LEDs/LED DIEs are still very expensive and the light yield is not very high.

In a further variant, the phosphor mixtures are applied to the LED DIEs by means of spray coating prior to casting of the LEDs. This method is very complex and can be carried out only by means of expensive devices under cleanroom conditions.

In the known methods, the conversion pigment is distributed unevenly and inhomogeneously in the dispersion, and accordingly in the layer produced therefrom, and the converted light is emitted inhomogeneously as a result. Because the human eye is particularly sensitive to colour differences of white light, sorting (binning) of the light-emitting elements is important in order to obtain LEDs of a definite spectral colour (light temperature). This subsequent sorting process is very intensive in terms of resources and costs because each individual light-emitting element has to be measured and sorted/classified according to the emitted spectral colour (www.ledmagazine.com/news/5/2/11).

In another known method, light-emitting diodes of different colours, for example blue and yellow (two LEDs) or red, green and blue (RGB), are so combined that the combined light appears white. Additional optical components are required for better mixing of the light, however.

For practical reasons, the differently coloured LED chips are often integrated into a component. This method is widely used but is very complex and expensive owing to the additional electronics.

The object was, therefore, to overcome the above-mentioned disadvantages of the prior art and provide a plastics composition which avoids the inhomogeneous emission of the converted light in a light-emitting device and, in particular, also the production Likewise, such a light-emitting device is to be provided which is simple and inexpensive to produce in any form, consumes little energy and is insensitive to external influences.

As well as homogeneity of the light, the production of sufficiently high scattered-light intensities is also of interest. Within the scope of the present invention, scattered light is to be understood as being light that can be detected within angles of 20° or of 45° to the perpendicular of non-scattered light emerging from the plane of the light source/LED, where a relative scattered-light intensity of greater than 0.7, preferably greater than 0.85, at an angle of 20° and of greater than 0.4, preferably greater than 0.55, at an angle of 45° is to be achieved.

It has been possible to achieve these and other objects, which will become apparent to the person skilled in the art from the following description of the invention, by means of the plastics composition according to the invention and by means of a transparent or semi-transparent plastics moulding, in particular a transparent or semi-transparent cover sheet or film, made from that plastics composition, and by means of the device according to the invention, in which the plastics moulding is used.

Accordingly, the invention provides a plastics composition (Z) which contains specific conversion pigments (K) in specific concentration ranges and a substrate A, which is a transparent or semi-transparent plastics moulding, for example a transparent or semi-transparent plastics sheet or film containing the plastics composition Z, and which can be used in particular in light-emitting devices.

The invention also provides a device which emits white light in particular and consists of a plastics moulded body (referred to as substrate B hereinbelow), which has on at least part of its surface, one or more cavities equipped with LEDs or LED DIEs, and the substrate A according to the invention, which at least partially covers the side of the moulded body having the cavities and which can optionally be bonded to the substrate B by an additional adhesion-promoter or adhesive layer.

The substrate A and optionally the substrate B having the cavities can additionally contain light-scattering particles and/or be structured so as to scatter light.

The invention further provides a method for the production of the device according to the invention, wherein
a) the substrate B having one or more cavities is produced,
b) the cavity (cavities) is (are) equipped with one or more LEDs, preferably LED DIEs, which are connected together electrically,
c) the substrate A consisting of a transparent or semi-transparent plastics moulding, film or sheet containing conversion pigments K is applied, in such a manner that the substrate A at least partially covers the cavity (cavities) equipped with LEDs or LED DIEs.

“Cover” or “covers” within the scope of the invention means that the light used for the application radiates through the substrate A or the moulded body containing the conversion pigments and is thereby partially colour converted. The substrate A can be mounted directly in front of or at a certain distance in front of the light-emitting element or in front of the substrate B having one or more cavities equipped with an electroluminescent element or one or more LEDs, preferably LED DIEs, it can be bonded directly to the light-emitting element by means of a transparent adhesive/adhesion promoter, or it can be attached to a moulded body or housing in which the light-emitting element is located, for example by adhesive bonding or a mechanical fastening, or it can be attached to a board or flexible conductor on which the light-emitting element is located.

Between the light-emitting element (e.g. LED or LED DIE) and the substrate A there can be one or more largely transparent adhesive layers, film layers or air.

The substrate A can also be arranged partially or completely around the substrate B. The production of the substrate A and of the substrate B is preferably carried out in a compounding and injection-moulding or extrusion step. The production process permits a reproducible, standardised product.

Fundamental to the invention is the composition of plastics material according to the invention (referred to as “Z” hereinbelow), containing specific conversion pigments K in specific concentrations (conc. B), which simultaneously permits light conversion and scattering of LED light in a homogeneous manner.

The composition Z according to the invention is suitable, for example, for the production of the substrate A, which can be used, for example, in the described device in combination with the moulded bodies containing LEDs or LED DIEs. This device is only an example of how the composition according to the invention can advantageously be used; further possibilities will become apparent to the person skilled in the art from known LED-containing devices. It is important that the substrate A, for example the film or sheet according to the invention, which contains the conversion pigments K is positioned between the LED-light source and the observer. The conversion pigment K can additionally also be present in the substrate B, which contains the LED or LED DIEs, itself.

The device according to the invention comprises a plastics moulded body (substrate B) which is provided with one or more cavities. The cavities are equipped with LEDs, preferably LED DIEs, which are connected together electrically. The plastics moulded body with the LEDs or DIEs can optionally be cast with a silicone- or polyurethane-based casting compound, which is optionally applied as adhesion promoter in the form of an adhesive layer. The substrate A, which contains the evenly distributed conversion pigments K and has scattering properties, is then applied.

Both organic and inorganic pigments are suitable as the conversion pigment K. Within the scope of the invention, conversion pigment is also understood as being a mixture of two or more different conversion pigments.

Surprisingly, it has been found that the compositions Z are most suitable for the production of light-converting and light-scattering substrates when their content of conversion pigments K is within a concentration range from 7 to 20 wt. %, preferably from 10 to 15 wt. %. Both below and above those limits there is a decline in the properties of the compositions Z in respect of the object underlying the invention.

As organic pigments there can be used, for example, so-called daylight pigments, such as the T series or FTX series from Swada or the daylight luminescent pigments from Sinloihi, such as, for example, the FZ-2000 series, FZ-5000 series, FZ-6000 series, FZ-3040 series, FA-40 series, FA-200 series, FA-000 series, FM-100, FX-300 or SB-10.

As materials for inorganic pigments there can be used garnets or oxinitrides, such as, for example, (Y, Gd, Lu, Tb)₃(Al, Ga)₅O₁₂ doped with Ce, (Ca, Sr, Ba)₂SiO₄ doped with Eu, YSiO₂N doped with Ce, Y₂Si₃O₃N₄ doped with Ce, Gd₂Si₃O₃N₄ doped with Ce, (Y, Gd, Tb, Lu)₃Al₅-xSixO₁₂-xNx doped with Ce, BaMgAl₁₀O₁₇ doped with Eu, SrAl₂O₄ doped with Eu, Sr₄Al₁₄O₂₅ doped with Eu, (Ca, Sr, Ba)Si₂N₂O₂ doped with Eu, SrSiAl₂O₃N₂ doped with Eu, (Ca, Sr, Ba)₂Si₂N₈ doped with Eu, CaAlSiN₃ doped with Eu; molybdates, tungstates, vanadates, nitrides and/or oxides of boron, aluminium, gallium, indium and thallium, in each case individually or mixtures thereof with one or more activator ions such as Ce, Eu, Mn, Cr and/or Bi.

The conversion pigments K according to the invention are particularly preferably inorganic pigments which contain Si, Sr, Ba, Ca and Eu in concentrations >0 ppm and Al, Co, Fe, Mg, Mo, Na, Ni, Pd, P, Rh, Sb, Ti and Zr in concentrations ≦50 ppm (including 0 ppm).

Both the plastics composition Z and the substrate A contain as base material preferably transparent polymeric materials, which are preferably selected from the group of the plastics materials consisting of polyolefins, such as polyethylene (PE) and polypropylene (PP), polyesters, for example polyalkylene terephthalates, such as polyethylene terephthalate (PET) and polybutylene terephthalate (PBT), cyanoacrylate (CA), cellulose triacetate (CTA), ethylvinyl acetate (EVA), propylvinyl acetate (PVA), polyvinylbutyral (PVB), polyvinyl chloride (PVC), polycarbonate (PC), polyethylene naphthalate (PEN), polyurethane (PU), thermoplastic polyurethane (TPU), polyamide (PA), polymethyl methacrylate (PMMA), polystyrene (PS), cellulose nitrate and copolymers of at least two of the monomers of the above-mentioned polymers, as well as mixtures of two or more of those polymers.

Suitable polycarbonates within the scope of the present invention are all known polycarbonates. These are homopolycarbonates, copolycarbonates and thermoplastic polyester carbonates.

The suitable polycarbonates preferably have mean molecular weights Mw of from 10,000 to 50,000, preferably from 14,000 to 40,000 and in particular from 14,000 to 35,000, determined by measuring the relative solution viscosity in dichloromethane or in mixtures of equal amounts by weight of phenol/o-dichlorobenzene calibrated by light scattering.

The polycarbonates are preferably prepared by the interfacial process or the melt transesterification process, which are variously described in the literature. Regarding the interfacial process, reference may be made, for example, to H. Schnell, “Chemistry and Physics of Polycarbonates”, Polymer Reviews, Vol. 9, Interscience Publishers, New York 1964 p. 33 ff, to Polymer Reviews, Vol. 10, “Condensation Polymers by Interfacial and Solution Methods”, Paul W. Morgan, Interscience Publishers, New York 1965, Chap. VIII, p. 325, to Dres. U. Grigo, K. Kircher and P.R.-Müller “Polycarbonate” in Becker/Braun, Kunststoff-Handbuch, Volume 3/1, Polycarboante, Polyacetale, Polyester, Celluloseester, Carl Hanser Verlag Munich, Vienna 1992, p. 118-145, and to EP-A 0 517 044.

The melt transesterification process is described, for example, in the Encyclopedia of Polymer Science, Vol. 10 (1969), Chemistry and Physics of Polycarbonates, Polymer Reviews, H. Schnell, Vol. 9, John Wiley and Sons, Inc. (1964) and in patent specifications DE-B 10 31 512 and U.S. Pat. No. 6,228,973.

The polycarbonates are preferably prepared by reactions of bisphenol compounds with carbonic acid compounds, in particular phosgene or, in the melt transesterification process, diphenyl carbonate or dimethyl carbonate. Homopolycarbonates based on bisphenol A and copolycarbonates based on the monomers bisphenol A and 1,1-bis-(4-hydroxyphenyl)-3,3,5-trimethylcyclohexane are particularly preferred. These and further bisphenol and diol compounds which can be used for polycarbonate synthesis are disclosed inter cilia in WO-A 2008037364 (p. 7, 1. 21 to p. 10, 1. 5), EP-A 1 582 549 ([0018] to [0034]), WO-A 2002026862 (p. 2, 1. 20 to p. 5, 1. 14), WO-A 2005113639 (p. 2, 1. 1 to p. 7, 1. 20).

The polycarbonates can be linear or branched. Mixtures of branched and unbranched polycarbonates can also be used.

Suitable branching agents for polycarbonates are known in the literature and are described, for example, in patent specifications U.S. Pat. No. 4,185,009 and DE-A 25 00 092 (3,3-bis-4-hydroxyaryl-oxindoles according to the invention, see whole document in each case), DE-A 42 40 313 (see p. 3, 1. 33 to p. 3, 1. 55), DE-A 19 943 642 (see p. 5, 1. 25 to p. 5, 1. 34) and U.S. Pat. No. 5,367,044 as well as in literature cited therein. In addition, the polycarbonates used can also be intrinsically branched, no branching agent being added within the scope of the polycarbonate preparation in this case. An example of intrinsic branchings are so-called Fries structures, as are disclosed for melt polycarbonates in EP-A 1 506 249.

Chain terminators can additionally be used in the polycarbonate preparation. Phenols such as phenol, alkylphenols such as cresol and 4-tert-butylphenol, chlorophenol, bromophenol, cumylphenol or mixtures thereof are preferably used as chain terminators.

It is possible for the plastics materials additionally to contain additives, such as, for example, UV absorbers, as well as other conventional processing aids, in particular demoulding agents and flow improvers, as well as stabilisers, in particular heat stabilisers, as well as antistatics, optical brightening agents or colourings. Colourings within the scope of the present invention are organic and inorganic pigments as well as dyes that are soluble in plastics materials.

In a particular embodiment, the composition Z is based on a cold-stretchable plastics composition. This is necessary in particular when a three-dimensionally formed film element is produced by isostatic high-pressure forming at a process temperature below the softening temperature of the plastics material. Suitable cold-stretchable plastics materials are mentioned, for example, in EP-A 0 371 425. Both thermoplastic and duroplastic, at least partially transparent cold-stretchable plastics materials can be used. Preference is given to the use of cold-stretchable plastics materials that exhibit low or no resilience at room temperature and use temperature. Particularly preferred plastics materials are selected from at least one material from the group consisting of polycarbonates, preferably polycarbonates based on bisphenol A, polyesters, in particular aromatic polyesters, for example polyalkylene terephthalates, polyamides, for example PA 6 or PA 6,6 types, high-strength “aramid films”, polyimides, for example films based on poly-(diphenyl oxide pyromellitimide), polyarylates, organic thermoplastic cellulose esters, in particular their acetates, propionates and acetobutyrates. Polycarbonates based on bisphenol A are most particularly preferably used as plastics materials. Films having the name Bayfol® CR (polycarbonate/polybutylene terephthalate film), Makrofol® TP or Makrofol® DE from Bayer MaterialScience AG are particularly preferred. Such formed films can then be adhesively bonded, stuck or screwed, for example, to the moulded body having the LEDs/LED-Dies.

In a particular embodiment, the substrate A is accordingly a plastics moulding, in particular a film or sheet, which is composed of at least one cold-stretchable plastics composition. Owing to the presence of the conversion pigments K in the composition Z in the concentrations according to the invention, the substrate A already has good scattering properties. The scattering properties can also be influenced further by the optional addition of further scattering additives.

The scattering property can be effected by internal structuring of the composition Z in the form of light-scattering particles, such as glass spheres, glass fibres, metal oxides, SiO₂ or minerals or organic scattering additives, for example core-shell acrylates or blends of immiscible polymers, which are incorporated into the moulded body or moulding and/or the film/sheet. The particles act as scattering centres for the incident light and deflect it in such a manner that it meets the surface of the plastics moulding, in particular the film/sheet, at a steep angle and is not subject to total reflection but is uncoupled. The same effect can be achieved with gas inclusions, which form interfaces at which the incident light is scattered. The particles can in turn also contain fluorescent substances.

The composition Z can contain further conventional plastics additives which are known to the person skilled in the art, for example, from WO 99/55772, p. 15-25, EP-A 1 308 804 and from the corresponding chapters of “Plastics Additives Handbook”, ed. Hans Zweifel, 5th Edition 2000, Hanser Publishers, Munich.

Substrate B likewise preferably consists of a plastics material, in particular of one or more of the above-mentioned polymers, optionally additionally containing the mentioned additives.

Another possibility for producing additional scattering properties both in substrate A and in substrate B is the structuring of the surface of the substrates by light-scattering particles which are incorporated into the surface. The particles act as scattering centres on the surface and uncouple the incident light.

The surface of the substrates, in particular of substrate A, can also be structured by means of grooves, flutes, channels and/or holes. In this type of surface structuring, scattering centres are formed on the surface. Lenticular structuring is also possible, in which the surface is provided with one or more lens-shaped elements.

The inorganic or organic, light-emitting elements (LEDs or LED DIEs) are covered wholly or partially by the substrate A. The substrate A thereby has a thickness d. It has now been found that efficient conversion and homogeneous distribution of light by the substrate A is achieved when the following relationship exists:

Concentration of the conversion pigment(wt. %)*thickness d [mm]=12−30,preferably 15−25 [wt. %*mm].

The wt. % here always relate to the total composition, in this case to the total composition of the substrate A.

As already described hereinbefore, “cover” or “covered” within the scope of the invention means that the light used for the application radiates through the substrate A or the moulded body containing the conversion pigments and is thereby partially colour converted. The substrate A can be mounted directly in front of or at a certain distance in front of the light-emitting element or in front of the substrate B having one or more cavities equipped with an electroluminescent element or one or more LEDs, preferably LED DIEs, it can be bonded directly to the light-emitting element by means of a transparent adhesive/adhesion promoter, or it can be attached to a moulded body or housing in which the light-emitting element is located, for example by adhesive bonding or a mechanical fastening, or it can be attached to a plate or flexible conductor on which the light-emitting element is located.

Between the light-emitting element (e.g. LED or LED DIE) and the substrate A there can be one or more largely transparent adhesive layers, film layers or air.

The substrate A can also be arranged partially or completely around the substrate B.

The light-emitting element can be one or more LEDs or LED DIEs or an electroluminescent element.

The final colour temperature of the light-emitting device is determined by the nature of the conversion pigment or mixture of conversion pigments, the degree of filling of the conversion pigment, the geometrical shape of the substrate A or of the moulded body, and the original emission wavelength of the light-emitting element. This colour temperature is determined and is reproducible under identical process conditions.

In order to produce the substrate A and/or the moulded body (substrate B) containing conversion pigments, the conversion pigments K are first incorporated into the transparent or semi-transparent plastics materials. Incorporation is carried out by known methods such as compounding or by dissolving the conversion pigments together with the polymer material and then concentrating.

The substrate A and its plastics mouldings and the substrate B and its plastics moulded bodies containing the conversion pigments K can be produced from the plastics materials containing the conversion pigments by known methods, such as, for example, injection moulding, extrusion, coextrusion, blow moulding or deep drawing. Films can also be produced from solvents by casting or other known coating methods. Laminates of a carrier and a film which contains the conversion pigments can also be used.

Solutions of conversion pigment and the plastics material can also be applied to a suitable substrate by methods such as casting, printing, spraying.

For internal structuring by the incorporation of particles, such as glass spheres or glass fibres, metal oxides, SiO₂ or minerals, or of organic scattering additives, the conventional methods for adding additives to plastics materials, for example compounding, are used. For internal structuring by means of gas inclusions, the conventional methods used, for example, in foam production can be employed.

For the structuring of the surface of the substrate A and/or of the substrate B, in a first step the particles are suspended in a solvent and applied to the surface of the substrate(s) by mechanical means or devices, such as, for example, a stamp or a printing machine. The areas in which the particles and the solvent touch the surface thereby swell. The solvent is then allowed to evaporate. To that end, the substrate B or the substrate A can be tempered until the solvent has evaporated completely.

Structuring of the surface of the substrate A and/or of the substrate B can also be carried out by grinding, scratching, peeling, cutting, boring, graining, stamping, laser ablation, dot matrix printing or other mechanical processes which result in a local deformation of or change in the surface. The surface can also be structured chemically by etching with a solvent.

The substrate A as a film or as a film with integrated lenses preferably has a thickness of from 10 μm to 3000 μm, preferably from 70 μm to 1500 μm, particularly preferably from 100 μm to 1000 μm, most particularly preferably from 125 μm to 750 μm.

The substrate A as an extruded sheet or as an extruded sheet with integrated lenses preferably has a thickness of from 1000 μm to 30,000 μm, preferably from 1200 μm to 15,000 μm, particularly preferably from 1500 μm to 10,000 μm.

The plastics composition Z according to the invention can be used, for example, for moulded bodies, sheets or films which are employed in lamps, lighting devices, illuminants equipped with LEDs in the interior and exterior sector, in particular in the transport sector, for example in motor vehicles, aircraft, ships, as interior lighting for living spaces and workspaces, in backlight units of LCD screens, in the exhibition stand construction and shop-fitting sector, in the furniture industry, for example accent lighting in kitchens, bedrooms, etc.

In a particular embodiment there is produced from Z the substrate A, which is used in the device which emits white light in particular and contains the substrate B having on at least part of its surface one or more cavities equipped with LEDs or LED DIEs, in such a manner that the substrate A according to the invention at least partially covers the side of the substrate B having the cavities and can optionally be bonded to the substrate B or to the LEDs or LED DIEs located therein by means of an adhesive layer.

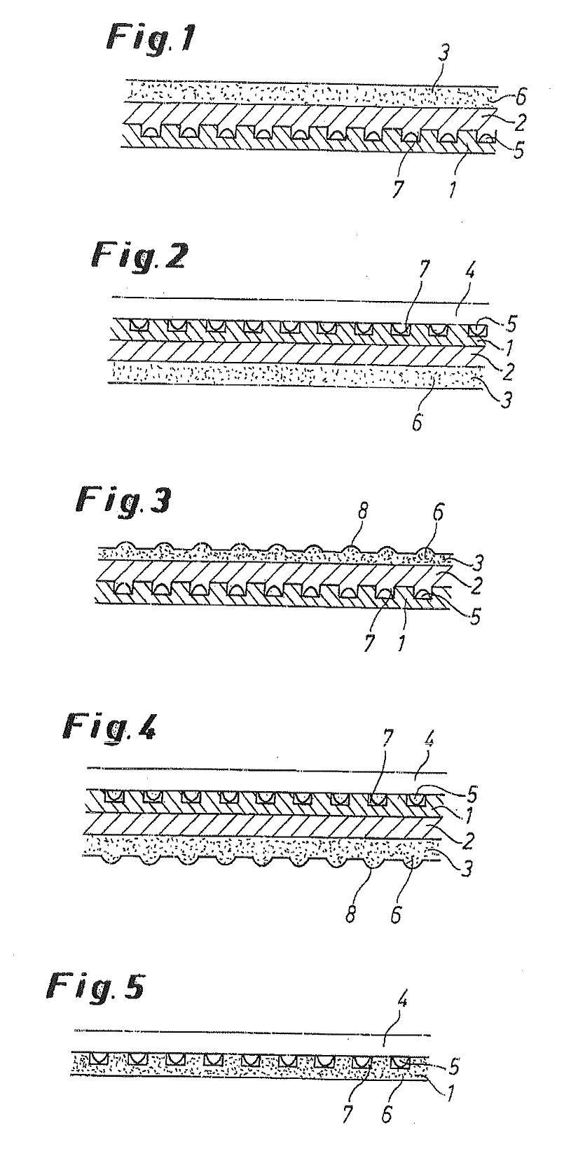

FIGS. 1 and 3 show devices which produce, for example, white LED light. The substrate B (1) has cavities (7) containing, for example, blue LEDs or LED-DIEs (5). A transparent casting compound or adhesive layer (2) serves as adhesion promoter between (1) and the substrate A (3), which contains conversion pigments (6), and protects the LEDs/LED DIEs (5). The substrate A (3) is in the form of a film (FIG. 1) or in the form of a film having focussing properties, for example microlenses (8) (FIG. 3).

Alternatively, the layer (2) consists of air and the substrate A is mounted at a distance in front of the substrate B and the LEDs by way of holding means.

In FIGS. 2 and 4, the devices producing, for example, white LED light have a moulded body (1) with cavities (7) and, for example, blue LEDs or LED DIEs (5), as well as a casting compound, plastics, ceramics or metal plate (4) as protection and for heat management. The transparent casting compound or adhesive layer (2) serves as adhesion promoter for the substrate A (3), which contains conversion pigments (6). The substrate A (3) is in form of a film (FIG. 2) or in the form of a film having focussing properties (e.g. microlenses (8)) (FIG. 4).

FIG. 5 shows another embodiment, in which a moulded body (1) contains cavities (7) in which LEDs are seated. In this case, the moulded body (1) is made of the composition Z and corresponds to the substrate A. The casting compound, plastics, ceramics or metal plate (4) serves as protection and for heat management.

A further embodiment of the invention is, for example, a device comprising a plastics moulded body which has on at least part of its surface cavities equipped with LEDs or LED DIEs, and a transparent or semi-transparent plastics film or sheet which at least partially covers the side of the moulded body having the cavities and which is optionally bonded to the plastics moulded body via an adhesive layer, characterised in that the transparent or semi-transparent plastics film or sheet and/or the plastics moulded body contains conversion pigments evenly distributed therein. This device can be used as a lamp, lighting device, illuminant for applications in the interior and exterior sector, in particular in the transport sector, for example in motor vehicles, aircraft, ships, as interior lighting for living spaces and workspaces, in backlight units of LCD screens, in the exhibition stand construction and shop-fitting sector, in the furniture industry, for example accent lighting in kitchens, bedrooms, etc.

A method for the production of this device can comprise the following steps:

a) a plastics moulded body with cavities is produced,
b) the cavities are equipped with LEDs or LED DIEs, which are connected together electrically,
c) an adhesion promoter is optionally applied and
d) a transparent or semi-transparent plastics film or sheet is applied, wherein
the transparent or semi-transparent plastics film or sheet and/or the plastics moulded body contain evenly distributed conversion pigments.

The compositions Z according to the invention and the effects according to the invention associated therewith are described by way of example hereinbelow. The examples are not, however, intended to limit the invention in any way.

### EXAMPLES

### Components Used for the Production of the Composition Z According to the Invention

### Polycarbonate Component A.

Makrolon 3108 (linear bisphenol A polycarbonate from Bayer AG, Leverkusen, having a melt volume flow rate (MVR) according to ISO 1133 of 6.0 cm³/10 min at 300° C. and a 1.2 kg load, a Vicat softening temperature of 149° C. at a load of 50 N and a heating rate of 50° C. per hour according to ISO 306, as well as a Charpy notched impact strength of 80 kJ/m² at 23° C. and a test specimen thickness of 3 mm according to ISO 179/1eA).

### Conversion Pigment B.

a) Conversion pigment F560, a europium-activated alkaline-earth orthosilicate in the form of a yellowish fluorescent powder having a mean particle size d₅₀ of 13.4 μm, obtainable from Leuchtstoffwerk Breitungen GmbH, 98597 Breitungen, Germany. In addition to the presence of europium, conversion pigment a) is characterised by further chemical elements, as follows:

| Element | Amount |
|---|---|
| Al, Co, Fe, Mg, Mo, Na, Ni, Ti | in each case 1 ppm-10 ppm |
| Pd, Rh | in each case 10 ppm-50 ppm |
| Ca | in each case 500 ppm-1000 ppm |
| Ba, Si, Sr | in each case >100,000 ppm |

b) Conversion pigment F565, a europium-activated alkaline-earth orthosilicate in the form of a yellowish fluorescent powder having a mean particle size d₅₀ of 12.1 μm, obtainable from Leuchtstoffwerk Breitungen GmbH, 98597 Breitungen, Germany. In addition to the presence of europium, conversion pigment b) is characterised by further chemical elements, as follows:

| Element | Amount |
|---|---|
| Fe, Mg, Mo, Ni, P, Ti | in each case 1 ppm-10 ppm |
| Al, Na, Pd, Rh | in each case 10 ppm-50 ppm |
| Ca | in each case 500 ppm-1000 ppm |
| Ba | 10,000 ppm-100,000 ppm |
| Si, Sr | in each case >100,000 ppm |

c) Conversion pigment LP-7912, a europium-activated alkaline-earth orthosilicate in the form of a yellowish fluorescent powder having a mean particle size d₅₀ of 12.1 μm, obtainable from Leuchtstoffwerk Breitungen GmbH, 98597 Breitungen, Germany. In addition to the presence of europium, conversion pigment c) is characterised by further chemical elements, as follows:

| Element | Amount |
|---|---|
| Co, Mo, Na, Ni, P, Ti | in each case 1 ppm-10 ppm |
| Mg, Pd, Rh | in each case 10 ppm-50 ppm |
| Ca | 100 ppm-500 ppm |
| Ba, Si, Sr | in each case >100,000 ppm |

Production of the Composition from the Components

The polycarbonate component A and the conversion pigment B were mixed with one another in powder form in the relative concentrations indicated in Table 1; the mixture was melted, and homogenisation was carried out in the molten state for 60 seconds. For that purpose, a DSM XPLORE 15 cm³ twin-screw micro-compounder mini-extruder (DSM) was used at a melt temperature of 310° C. The melt was then discharged by injection moulding by means of an injection-moulding machine of type TS/1-01 (DSM) associated with the extruder, at a tool temperature of 80° C., to give a plastics moulding in the form of sheets of thickness d=1.5 mm, and the sheets were cooled to room temperature.

### Testing of the Mouldings

### Angle-Dependent Scattered Light Measurement

The angle-dependent measuring of the scattered light was carried out on the sheets of thickness 1.5 mm produced by means of the DSM injection-moulding machine. A GON360 goniometer with a CAS140B spectrometer from Instrument Systems was used for that purpose. In the measurement, the lamp current of the light source was 8.5 A. The plate through which light radiated was arranged perpendicular to the light source. The intensity of the light emerging linearly from the light source was first measured perpendicularly to the plane of the sheet (position 0°), and then the scattered light was detected in a semicircular arc spanning measuring angles of 0° to 180°. In order to determine the relative scattered light intensities, the light intensities detected at each of the measuring angles was related to the intensity of the light measured at 0° (not scattered). The results of the test are given in Table 1.

TABLE 1

| Test number | 1 | 2 | 3 | 4* | 5* | 6* |
|---|---|---|---|---|---|---|
| Conversion pigment B | a) | b) | c) | a) | b) | c) |
| Concentration of conversion | 14.66 | 13.88 | 10.00 | 3.47 | 3.20 | 20.00 |
| pigment B | | | | | | |
| Conc. B [wt. %] | | | | | | |
| Concentration of component A | 85.34 | 86.12 | 90 | 96.53 | 96.80 | 80.00 |
| Conc. A [wt. %] | | | | | | |
| LED colour impression without | blue | blue | blue | blue | blue | blue |
| conversion sheet | | | | | | |
| LED colour impression with | white | white | white | blue | blue | yellow |
| conversion sheet | | | | | | |
| Thickness of the sheet | 1.5 | 1.5 | 1.5 | 1.5 | 1.5 | 1.5 |
| (plastics moulding of substrate A) | | | | | | |
| d [mm] | | | | | | |
| Relative scattered light intensity | 0.92 | 0.92 | 0.88 | 0.04 | 0.06 | 0.94 |
| at 20° | | | | | | |
| Relative scattered light intensity | 0.67 | 0.67 | 0.60 | 0.01 | 0.02 | 0.71 |
| at 45° | | | | | | |
| Conc. (B) × d | 21.99 | 20.82 | 15.00 | 5.21 | 4.80 | 30.00 |
| [wt. % * mm] | | | | | | |

*comparison tests

1-13. (canceled)

14. A composition comprising a plastic material and an inorganic conversion pigment present in an amount of 7 to 20 wt. %, wherein the conversion pigment comprises Si, Sr, Ba, Ca and Eu in concentrations of greater than 0 ppm and Al, Co, Fe, Mg, Mo, Na, Ni, Pd, P, Rh, Sb, Ti and Zr in concentrations of less than or equal to 50 ppm.

15. The composition according to claim 14, wherein the conversion pigment is present in an amount of 10 to 15 wt. %.

16. The composition according to claim 14, wherein the plastic material is selected from the group consisting of polycarbonates, polyethylene terephthalates, polybutylene terephthalates, polymethyl methacrylates, polyamides, and mixtures thereof.

17. The composition according to claim 14, wherein the plastic material comprises a polycarbonate selected from the group consisting of a homopolycarbonate based on bisphenol A, a copolycarbonate based on the monomers bisphenol A and 1,1-bis-(4-hydroxyphenyl)-3,3,5-trimethylcyclohexane, and mixtures thereof.

18. The composition according to claim 14, wherein the plastic material comprises a cold-stretchable plastic material.

19. The composition according to claim 14, wherein the composition further comprises a scattering additive, a colourant, or mixtures thereof.

20. A transparent or semi-transparent plastic moulded body or plastic moulding comprising the composition according to claim 14.

21. A transparent or semi-transparent plastic sheet or film comprising the composition according to claim 14.

22. A light-emitting device comprising the transparent or semi-transparent plastic moulded body or plastic moulding according to claim 20.

23. A light-emitting device comprising the transparent or semi-transparent plastic sheet or film according to claim 21.

24. A light-emitting device comprising a first plastic moulding, moulded body, sheet, or film made from the composition according to claim 14.

25. The light-emitting device according to claim 24, further comprising a second plastic moulded body which comprises a first surface comprising one or more cavities equipped with a light emitting diode or a light emitting diode chip, wherein the first plastic moulded body is a plastic sheet or film, and at least partially covers one or more of the cavities on the first surface of the second plastic moulded body.
